(19) United States
(12) Patent Application Publication
(10) Pub. No.: US 2025/0309124 A1
(43) Pub. Date: Oct. 2, 2025

(54) GLASS SUBSTRATE, SEMICONDUCTOR PACKAGE INCLUDING GLASS SUBSTRATE AND METHOD FOR MANUFACTURING THE SAME

(71) Applicant: Samsung Electronics Co., Ltd., Suwon-si (KR)

(72) Inventor: Junghoon KANG, Suwon-si (KR)

(73) Assignee: Samsung Electronics Co., Ltd., Suwon-si (KR)

(21) Appl. No.: 18/825,185

(22) Filed: Sep. 5, 2024

(30) Foreign Application Priority Data
Mar. 29, 2024 (KR) 10-2024-0043553

(51) Int. Cl. H01L 23/538; H01L 21/48; H01L 23/13; H01L 23/15; H01L 25/16

(52) U.S. Cl. CPC H01L 23/5385; H01L 21/486; H01L 23/13; H01L 23/15; H01L 25/162; H10D 1/68

(57) ABSTRACT

A glass substrate according may include a core layer and a plurality of capacitor structures. The core layer may include a glass core including a center region and an edge region around the center region, which maybe defined by dividing the plane of the glass core, a plurality of through-glass vias in the glass core in the center region, and a plurality of cavities in the edge region. The plurality of capacitor structures may be the plurality of cavities.

### CROSS-REFERENCE TO RELATED APPLICATION

This application claims priority to and the benefit of Korean Patent Application No. 10-2024-0043553, filed in the Korean Intellectual Property Office on Mar. 29, 2024, the entire contents of which are incorporated herein by reference.

### BACKGROUND

### (a) Field

The present disclosure relates to a glass substrate, a semiconductor package including the glass substrate, and a method for manufacturing the same.

### (b) Description of the Related Art

As semiconductor technology advances, demand may increase for semiconductor packages including semiconductor dies with high-performance circuits that enable digital signals to be processed at high speeds. In these semiconductor packages including high-performance semiconductor dies, power integrity (PI) characteristics may be important. In order to improve power integrity, it may be required to implement decoupling capacitors, which may be disposed inside semiconductor packages, so as to have high capacitance.

To this end, in the related art, power characteristics have been enhanced in the manner of providing capacitance required for high-performance semiconductor dies from decoupling capacitors inside cavities by forming cavities inside an organic substrate and embedding multilayer ceramic capacitors (MLCCs) in the cavities or forming thin film capacitors (TFCPs) inside the cavities.

Meanwhile, in response to demands for miniaturization of semiconductor packages, a glass substrate, where fine-pitch I/O terminals can be formed, may be adopted as products to replace the organic substrate having general-pitch I/O terminals. However, when glass materials are cut with lasers in order to form cavities for embedding decoupling capacitors in the glass substrate, around the laser cutting areas, microcracking may occur or heat affected zones (HAZs) which are impacted by stress may be generated, resulting in deterioration of the mechanical characteristics of the glass substrates.

### SUMMARY

The present disclosure relates to forming through-holes and cavities in a glass wafer including glass cores through an operation of modifying the glass wafer according to the patterns of through-holes to be formed in center regions of the glass cores and according to the patterns of cavities to be formed in edge regions of the glass cores, using a laser, and an operation of performing etching on the glass wafer. An operation of singulation of the glass cores from the glass wafer may be performed by laser cutting.

The cavities may include whole cavities or half cavities. In an embodiment, in which the cavities are half cavities, an insulating member may be on the side surfaces of capacitor structures and side surfaces of the glass cores which are exposed after singulation into the glass cores is performed.

The capacitor structures may be formed in the manner of performing a process of forming a capacitor in the cavities, respectively, or may be formed in the manner of mounting premanufactured a capacitor chip inside the cavities.

A glass substrate according to an embodiment may include a core layer including a glass core including a center region and an edge region around the center region, which may be defined by dividing a plane of the glass core, a plurality of through-glass vias inside the glass core in the center region, and a plurality of cavities in the edge region; and a plurality of capacitor structures in the plurality of cavities.

A semiconductor package according to an embodiment may include a glass substrate including a core layer, a first buildup structure on a first surface of the core layer, a second buildup structure on a second surface of the core layer, the second surface of the core layer being opposite the first surface of the core layer, and a plurality of capacitor structures inside the core layer; and a semiconductor die on the glass substrate. The core layer may include a glass core including a center region and an edge region around the center region, which may be defined by dividing a plane of the glass core, a plurality of through-glass vias inside the glass core in the center region, and a plurality of cavities in the edge region, and a plurality of capacitor structures in the plurality of cavities.

A method for manufacturing a glass substrate according to an embodiment may include providing a glass wafer including a plurality of glass cores, wherein each of the plurality of glass cores may include a center region and an edge region around the center region; modifying the glass wafer with a laser, the modifying the glass wafer including forming first modification patterns in in the center region and second modification patterns in the edge region; performing etching on the glass wafer, the performing etching forming a plurality of through-holes in the center region by removing the first modification patterns and forming a plurality of cavities in the edge region by removing the second modification patterns; forming a plurality of through-glass vias by filling the plurality of through-holes with a conductive material; forming capacitor structures in the plurality of cavities; and singulating a plurality of glass cores from the glass wafer.

The operation of forming the through-holes and the cavities in the glass core may be performed by laser modification and etching. Inside each of the through-holes and the cavities formed by the composite process, structures having ultrafine shapes capable of ensuring adhesion strength to a conductive material may be formed. Further, the inside of the through-holes and the cavities formed by the composite process has a very low value of surface roughness. Since the operation of singulation of the glass core may be performed by laser cutting, the side surfaces of the glass core obtained by the singulation may have a shape different from the inner shape of the through-holes and the cavities.

By directly connecting the glass core where the capacitor structures are disposed and a high-performance semiconductor die, it is possible to reduce the size of a semiconductor package. As a result, the distances of the capacitor structures and the high-performance semiconductor die decrease. Therefore, it is possible to improve the decoupling effect of the capacitor structures.

By forming the through-vias in the center region of the glass core and disposing the capacitor structures in the edge region of the glass core, it is possible to more efficiently implement a power transfer path and a signal transfer path, and it is possible to reduce the size of the semiconductor package.

In the embodiment in which the cavities are half cavities, an insulating member may be disposed on the side surface of capacitor structure and side surfaces of the glass core which are exposed after singulation into the glass cores, thereby reinforcing the stiffness of the glass substrate.

### BRIEF DESCRIPTION OF THE DRAWINGS

FIG. 1 is a cross-sectional view illustrating a semiconductor package of an embodiment.

FIG. 2 is a plan view of a core layer of the semiconductor package of FIG. 1, taken along line A-A′.

FIGS. 3 to 20 are cross-sectional views for explaining a method for manufacturing the semiconductor package of FIG. 1.

FIG. 21 is a cross-sectional view illustrating a semiconductor package of another embodiment.

FIG. 22 is a plan view of a core layer of the semiconductor package of FIG. 21, taken along line C-C′.

FIGS. 23 to 31 are cross-sectional views for explaining a method for manufacturing the core layer of the semiconductor package of FIG. 21.

FIG. 32 is a cross-sectional view illustrating a semiconductor package of a further embodiment.

FIGS. 33 to 36 are cross-sectional views for explaining a method for manufacturing a core layer of the semiconductor package of FIG. 32.

### DETAILED DESCRIPTION OF THE EMBODIMENTS

In the following detailed description, only certain embodiments of the present disclosure have been shown and described, simply by way of illustration. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present disclosure is not limited thereto.

Throughout this specification, when a part is referred to as being “connected” to another part, it may be directly connected to the other part, or may be connected to the other part indirectly with any other elements interposed therebetween. In addition, unless explicitly described to the contrary, the word “comprise”, and variations such as “comprises” or “comprising”, will be understood to imply the inclusion of stated elements but not the exclusion of any other elements.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “above” or “on” a reference portion, the element is located above or below the reference portion, and it does not necessarily mean that the element is located “above” or “on” in a direction opposite to gravity.

Further, in the entire specification, when it is referred to as “on a plane”, it means when a target part is viewed from above, and when it is referred to as “on a cross-section”, it means when the cross-section obtained by cutting a target part vertically is viewed from the side.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereinafter, a glass substrate 110 of an embodiment, a semiconductor package 100 including the glass substrate 110, and a method for manufacturing the same will be described with reference to the drawings.

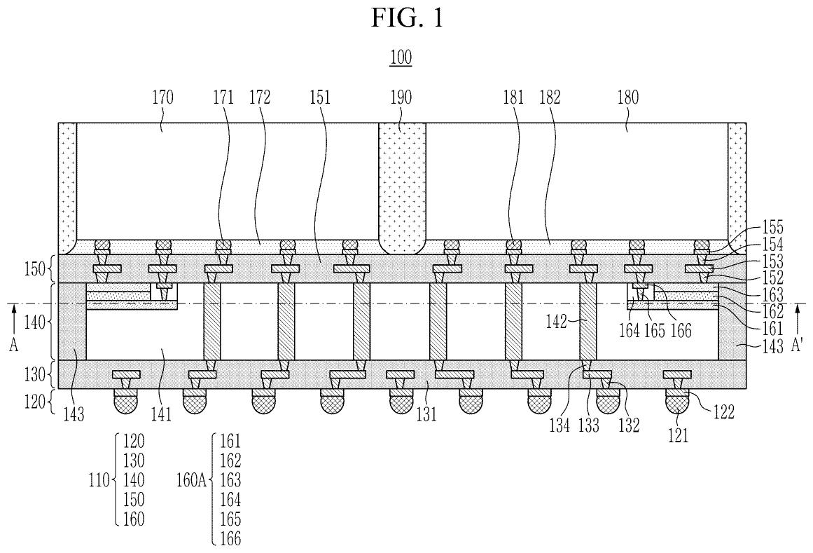

FIG. 1 is a cross-sectional view illustrating a semiconductor package 100 of an embodiment.

Referring to FIG. 1, the semiconductor package 100 may include a glass substrate 110, a first semiconductor die 170, first connection members 171, a first insulating member 172, a second semiconductor die 180, second connection members 181, a second insulating member 182, and a molding material 190. In the embodiment, the semiconductor package 100 may include a 2.5D semiconductor package. In the 2.5D semiconductor package, the first semiconductor die 170 and the second semiconductor die 180 may be disposed on the glass substrate 110, and the glass substrate 110 may electrically connect the first semiconductor die 170 and the second semiconductor die 180 to each other, and may electrically connect the first semiconductor die 170 and the second semiconductor die 180 to an external device. In the embodiment the semiconductor package 100 may be manufactured based on a fan-out wafer-level packaging (FOWLP) or fan-out panel-level packaging (FOPLP) technology.

The glass substrate 110 may include an external connection structure 120, a lower buildup structure (a first buildup structure) 130, a core layer 140, an upper buildup structure (a second buildup structure) 150, and capacitor structures 160 (first capacitor structures 160A).

The external connection structure 120 may be disposed on the lower surface of the lower buildup structure 130. The external connection structure 120 includes external connection member 121 and connection pads 122. The external connection members 121 electrically connect the glass substrate 110 to an external device (not shown in the drawings). The external connection members 121 may be disposed below the connection pads 122. The external connection members 121 may be electrically connected to the connection pads 122. The connection pads 122 may be disposed between the first vias 132 of the lower buildup structure 130 and the external connection members 121. The connection pads 122 may electrically connect the first vias 132 of the lower buildup structure 130 to the external connection members 121.

The lower buildup structure 130 may be disposed on the external connection structure 120. The lower buildup structure 130 may include a first dielectric 131 and first circuit wiring lines inside the first dielectric 131. The first circuit wiring lines may include the first vias 132, first conductive lines 133, and second vias 134.

The first dielectric 131 protects and insulates the first vias 132, the first conductive lines 133, and the second vias 134. On the upper surface of the first dielectric 131, the core layer 140 may be disposed. On the lower surface of the first dielectric 131, the external connection structure 120 may be disposed.

The first vias 132 may be disposed between the first conductive lines 133 and the connection pads 122. The first vias 132 may electrically connect the first conductive lines 133 to the connection pads 122 in the vertical direction. The first conductive lines 133 may be disposed between the first vias 132 and the second vias 134. The first conductive lines 133 may electrically connect the first vias 132 and the second vias 134 in the horizontal direction. The second vias 134 may be disposed between the first conductive lines 133 and the through-glass vias (TGVs) 142. The second vias 134 may electrically connect the through-glass vias (TGVs) 142 to the first conductive lines 133. In other embodiments, the lower buildup structure 130 may include fewer or more conductive lines and vias, which also is included in the scope of the present disclosure.

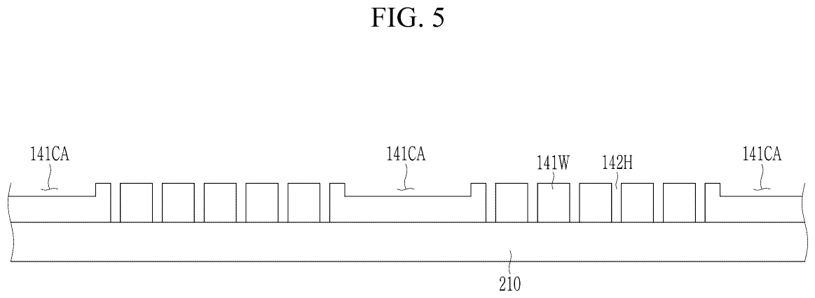

The core layer 140 may be disposed on the lower buildup structure 130. The core layer 140 may include a glass core 141, the through-glass vias (TGVs) 142, first cavities 141CA (see FIG. 5), and an insulating member 143. The glass core 141 may include a center region R1 and an edge region R2 around the center region R1. In the center region R1, the through-glass vias (TGVs) 142 may be disposed. In the edge region R2, the first cavities 141CA may be disposed. In the embodiment, the glass core 141 may include borosilicate glass, quartz, or alkali-free glass.

As compared to polymer materials that have been used as cores of organic substrates in the related art, the glass material can form finer circuit patterns. Accordingly, when the glass core 141 is used to manufacture a semiconductor package, it may not be necessary to use an interposer to connect a high-performance semiconductor die having I/O terminals with a fine pitch and an organic substrate having I/O terminals with a general pitch, unlike semiconductor packages according to the related art, and thus it is possible to reduce the size of the semiconductor package.

The through-glass vias (TGVs) 142 may be positioned in the glass core 141. The through-glass vias (TGVs) 142 may be positioned in the center region R1. The through-glass vias (TGVs) 142 may be disposed between the second vias 134 of the lower buildup structure 130 and each of third vias 152 of the upper buildup structure 150. The through-glass vias (TGVs) 142 may electrically connect the each of third vias 152 of the upper buildup structure 150 to the second vias 134 of the lower buildup structure 130.

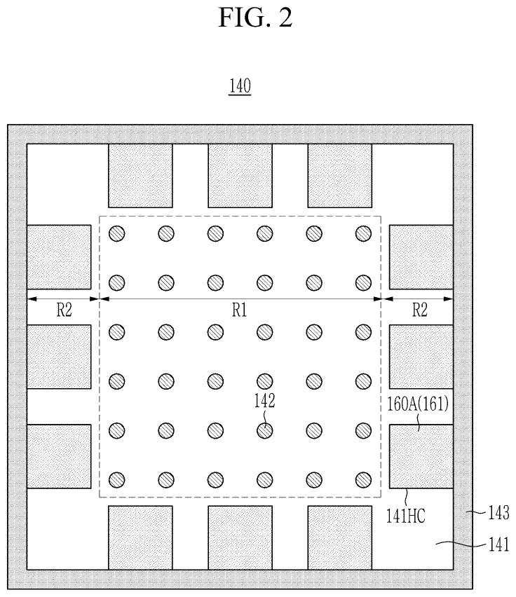

The first cavities 141CA may be formed in the edge region R2 of the glass core 141. The first cavities 141CA may include a half cavity 141HC (see FIG. 2).

The insulating member 143 may be disposed next to the glass core 141 and around the glass core 141. The insulating member 143 surrounds the side surfaces of the glass core 141 and the exposed side surface of the first capacitor structures 160A. The insulating member 143 protects the exposed side surface of the first capacitor structures 160A formed in the half cavities 141HC. Further, by disposing the insulating member 143 on the side surfaces of the glass core 141 and the exposed side surface of the first capacitor structures 160A, it is possible to reinforce the stiffness of the glass substrate 110.

The upper buildup structure 150 may be disposed on the core layer 140. The upper buildup structure 150 may include a second dielectric 151, second circuit wiring lines inside the second dielectric 151, and bonding pads 155 on the second dielectric 151. The second circuit wiring lines may include the third vias 152, second conductive lines 153, and fourth vias 154.

The second dielectric 151 protects and insulates the third vias 152, the second conductive lines 153, and the fourth vias 154. On the upper surface of the second dielectric 151, a first insulating film 172, a second insulating film 182, and the molding material 190 may be disposed. On the lower surface of the second dielectric 151, the core layer 140 may be disposed.

The third vias 152 may be disposed between the through-glass vias (TGVs) 142 and the second conductive lines 153, between upper electrodes 163 and the second conductive lines 153, or between connection pads 166 and the second conductive lines 153. The third vias 152 may electrically connect the second conductive lines 153 to the through-glass vias (TGVs) 142, the second conductive lines 153 to the upper electrodes 163, or the second conductive lines 153 to the connection pads 166. The second conductive lines 153 may be disposed between the third vias 152 and the fourth vias 154. The second conductive lines 153 may electrically connect the third vias 152 to the fourth vias 154 in the horizontal direction. The fourth vias 154 may be disposed between the second conductive lines 153 and the bonding pads 155. The fourth vias 154 may electrically connect the bonding pads 155 to the second conductive lines 153. In other embodiments, the upper buildup structure 150 may include fewer or more conductive lines, vias, and bonding pads, which also is included in the scope of the present disclosure.

The first capacitor structures 160A may be positioned inside the half cavities 141HC of the glass core 141. The first capacitor structures 160A may be positioned in the edge region R2. In the embodiment, the first capacitor structures 160A may include thin film capacitors (TFCPs). The first capacitor structures 160A may include a lower electrode 161, a dielectric layer 162, the upper electrode 163, a dielectric 164, a via 165, and the connection pad 166. The first capacitor structures 160A may be disposed inside the half cavities 141HC (see FIG. 2) of the glass core 141. Since the first capacitor structures 160A may be disposed inside the half cavities 141HC, the first capacitor structures 160A include side surface exposed from the glass core 141. These side surface may be in contact with the insulating member 143.

The lower electrode 161 may be positioned on at least portion of the bottom surface of the half cavity 141HC. Since the lower electrode 161 may be positioned inside the half cavity 141HC, the lower electrode 161 includes side surface exposed from the glass core 141. These side surface of the lower electrode 161 may be in contact with the insulating member 143. The other side surfaces of the lower electrode 161 may be in contact with the glass core 141. The lower electrode 161 has a thin film shape. The lower electrodes 161 may be electrically connected to the third via 152 of the upper buildup structure 150 through the via 165 and the connection pad 166. In other embodiments, the lower electrode 161 may be electrically connected to the second via 134 of the lower buildup structure 130.

The dielectric layer 162 may be positioned on at least portion of the lower electrode 161. Since the dielectric layer 162 may be positioned inside the half cavity 141HC, the dielectric layer 162 may include a side surface exposed from the glass core 141. These side surface of the dielectric layer 162 may be in contact with the insulating member 143. The other side surfaces of the dielectric layer 162 may be in contact with a dielectric 164 or the glass core 141. The dielectric layer 162 may have a thin film shape.

The upper electrode 163 may be positioned on at least portion of the dielectric layer 162. Since the upper electrode 163 may be positioned inside the half cavity 141HC, the upper electrode 163 includes side surface exposed from the glass core 141. The side surface of the upper electrode 163 may be in contact with the insulating member 143. The other side surfaces of the upper electrode 163 may be in contact with a dielectric 164 or the glass core 141. The upper electrode 163 have a thin film shape. The upper electrodes 163 may be electrically connected to the third via 152 of the upper buildup structure 150.

The dielectric 164 may be positioned on the lower electrode 161. The dielectric 164 protect and insulate the via 165 and the connection pad 166. The via 165 may be disposed between the lower electrode 161 and the connection pad 166. The via 165 electrically connect the connection pad 166 to the lower electrode 161. The connection pad 166 may be disposed between the via 165 and the third via 152 of the upper buildup structure 150. The connection pad 166 electrically connect the third via 152 of the upper buildup structure 150 to the via 165.

The first semiconductor die 170 may be disposed on the glass substrate 110. The first semiconductor die 170 may be disposed side by side with the second semiconductor die 180. The first semiconductor die 170 may be disposed next to the second semiconductor die 180. In the embodiment, the first semiconductor die 170 may include a logic die. In the embodiment, the first semiconductor die 170 may include an application processor (AP). In the embodiment, the first semiconductor die 170 may include at least one of central processing units (CPUs) and graphic processing units (GPUs).

The first connection members 171 may be disposed between the upper buildup structure 150 of the glass substrate 110 and the first semiconductor die 170. The first connection members 171 may be disposed between the bonding pads 155 of the upper buildup structure 150 of the glass substrate 110 and the first semiconductor die 170. The first connection members 171 may electrically connect the first semiconductor die 170 to the bonding pads 155 of the upper buildup structure 150 of the glass substrate 110.

The first insulating member 172 may be disposed between the upper buildup structure 150 of the glass substrate 110 and the first semiconductor die 170. The first insulating member 172 surrounds and insulates some portions of the bonding pads 155 and the first connection members 171.

The second semiconductor die 180 may be disposed on the glass substrate 110. The second semiconductor die 180 may be disposed side by side with the first semiconductor die 170. The second semiconductor die 180 may be disposed next to the first semiconductor die 170. In the embodiment, the second semiconductor die 180 may include a memory die. In the embodiment, the second semiconductor die 180 may be a high bandwidth memory (HBM).

The second connection members 181 may be disposed between the upper buildup structure 150 of the glass substrate 110 and the second semiconductor die 180. The second connection members 181 may be disposed between the bonding pads 155 of the upper buildup structure 150 of the glass substrate 110 and the second semiconductor die 180. The second connection members 181 may electrically connect the second semiconductor die 180 to the bonding pads 155 of the upper buildup structure 150 of the glass substrate 110.

The second insulating member 182 may be disposed between the upper buildup structure 150 of the glass substrate 110 and the second semiconductor die 180. The second insulating member 182 surrounds and insulates some portions of the bonding pads 155 and the second connection members 181.

The molding material 190 may be disposed on the glass substrate 110. The molding material 190 covers the first semiconductor die 170, the first insulating member 172, the second semiconductor die 180, and the second insulating member 182.

According to the present disclosure, by disposing the first semiconductor die 170 and the second semiconductor die 180 directly on the glass substrate 110 with the first capacitor structures 160A disposed therein, it is possible to reduce the size of the semiconductor package 100. As a result, the distance between the first semiconductor die 170 and the second semiconductor die 180 and one of the first capacitor structures 160A corresponding thereto decreases. Therefore, it is possible to improve the decoupling effect of the first capacitor structures 160A.

FIG. 2 is a plan view of the core layer 140 of the semiconductor package 100 of FIG. 1, taken along line A-A′.

Referring to FIG. 2, with respect to a dotted line, the glass core 141 of the core layer 140 includes the center region R1 inside the dotted line and the edge region R2 outside the dotted line. The center region R1 and the edge region R2 may be defined by dividing the plane of the glass core 141. In the center region R1, the through-glass vias (TGVs) 142 may be disposed. In the edge region R2, the half cavities 141HC may be positioned, and the first capacitor structures 160A may be disposed inside the half cavities 141HC, respectively. One side surface of the first capacitor structures 160A may be in contact with the insulating member 143, and the other side surfaces may be in contact with the glass core 141. The one side surface of the first capacitor structures 160A and the side surfaces of the glass core 141 may be surrounded by the insulating member 143. In other embodiment, the core layer 140 may include fewer or more through-glass vias and capacitor structures, which also is included in the scope of the present disclosure.

According to the present disclosure, by forming the through-glass vias (TGVs) 142 in the center region R1 of the glass core 141 and disposing the first capacitor structures 160A in the edge region R2 of the glass core 141, it is possible to more efficiently implement a power transfer path and a signal transfer path, and it is possible to reduce the size of the semiconductor package 100.

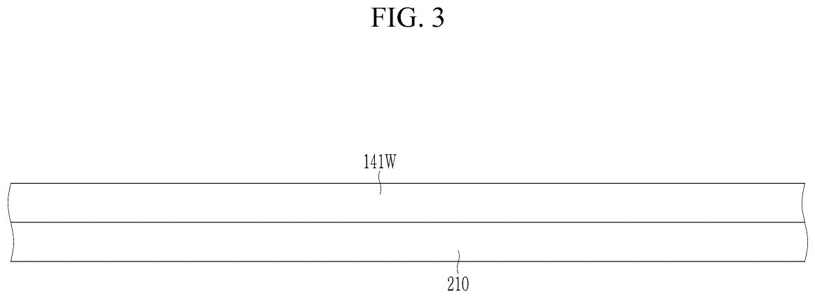

FIGS. 3 to 20 are cross-sectional views for explaining a method for manufacturing the semiconductor package 100 of FIG. 1. Among them, FIGS. 3 to 11 are cross-sectional views for explaining an operation of forming glass cores 141 from a glass wafer 141W.

FIG. 3 is a cross-sectional view illustrating an operation of providing the glass wafer 141W on a carrier 210.

Referring to FIG. 3, the glass wafer 141W on the carrier 210 may be provided. In the embodiment, the carrier 210 may comprise a silicon-based material such as glass or silicon oxide, an organic material, or other materials such as aluminum oxide, any combination of these materials, etc. In the embodiment, the glass wafer 141W may include borosilicate glass, quartz, or alkali-free glass.

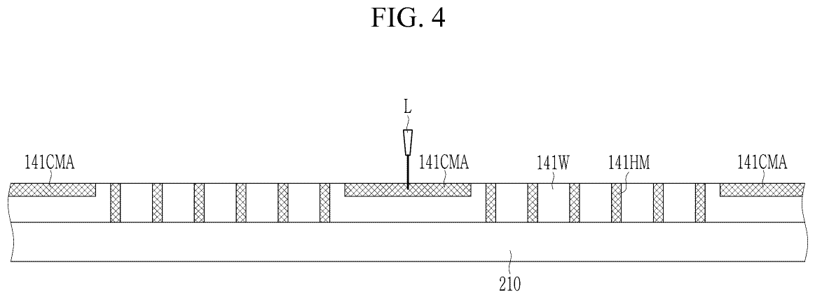

FIG. 4 is a cross-sectional view illustrating an operation of modifying the glass wafer 141W with a laser L.

Referring to FIG. 4, according to the patterns of through-holes 142H (see FIG. 5) to be formed in the center region R1 and according to the patterns of the first cavities 141CA to be formed in the edge region R2, the glass wafer 141W may be modified by a laser beam from the laser L. The laser beam from the laser L forms first modification patterns 141HM and second modification patterns 141CMA in the glass wafer 141W without destroying the glass wafer 141W. The first modification patterns 141HM may be patterns for forming the through-holes 142H. The second modification patterns 141CMA may be patterns for forming the first cavities 141CA. The laser beam modifies the mesh structure of the glass wafer 141W into a linear chain structure. The modification on the glass wafer 141W may be performed along the beam axis of the laser beam. The laser beam has the form of a pulse sequence and interacts with the glass wafer 141W. The pulse sequence may include single pulses. In an embodiment, the laser beam used for modification may have a pulse width shorter than about 100 ns. In an embodiment, the laser beam used for modification may have a pulse width shorter than about 1 fs.

FIG. 5 is a cross-sectional view illustrating an operation of etching the glass wafer 141W.

Referring to FIG. 5, by etching the glass wafer 141W, the through-holes 142H may be formed in the center region R1 and the first cavities 141CA may be formed in the edge region R2. In an embodiment, the operation of etching the glass wafer 141W may be performed by isotropic wet etching. When the etching process is performed, the portions of the glass wafer 141W that have not been modified into the linear chain structure may be rarely etched, and the first modification patterns 141HM and second modification patterns 141CMA of the glass wafer 141W that have been modified into the linear chain structure by the laser beam may be rapidly etched. Accordingly, etching may be performed along the outlines of the first modification patterns 141HM and the second modification patterns 141CMA by the laser.

The inner surface of the through-holes 142H and the first cavities 141CA formed through the process of the two operations of modification by the laser beam and etching has a shape different from the surface shape formed by laser cutting the glass wafer 141W. In an embodiment, the inner surface of the through-holes 142H and the first cavities 141CA may have a porous shape or a wavy shape. In an embodiment, the inner surface of the through-holes 142H and the first cavities 141CA may have a shape in which contraction portions and extension portions may be regularly or irregularly formed. In an embodiment, the inner surface of the through-holes 142H and the first cavities 141CA may have a shape in which contraction portions and extension portions may be continuously or discontinuously extended. The shapes of the above-mentioned embodiments may be ultrafine shapes, and this ultrafine shape of the inner surface of the through-holes 142H and the first cavities 141CA ensures excellent adhesion strength to a conductive material or a dielectric material to be subsequently deposited on the inside of the through-holes 142H and the first cavities 141CA.

The surface roughness of the inner surface of the through-holes 142H and the first cavities 141CA formed through the process of the two operations of modification by the laser beam and etching has a value smaller than that of the surface roughness of the surface that is formed by performing laser cutting on the glass wafer 141W. In an embodiment, the surface roughness of the inner surface of the through-holes 142H and the first cavities 141CA may be about 2 nm to about 40 nm. This low surface roughness of the inner surface of the through-holes 142H and the first cavities 141CA improves the reliability of the through-glass vias (TGVs) 142 that may be formed by filling the through-holes 142H with a conductive material and the reliability of the first capacitor structures 160A that may be formed inside the first cavities 141CA.

When cutting (drilling) is performed on the glass wafer 141W with the laser in order to form the through-holes 142H or the first cavities 141CA, around the laser cutting areas, microcracking may occur or heat affected zones (HAZs) which are impacted by stress may be generated, resulting in deterioration of the mechanical characteristics of the glass wafer 141W. According to the present disclosure, since the composite process of modification by the laser beam and etching may be performed to form the through-holes 142H and the first cavities 141CA in the glass wafer 141W, microcracking does not occur in the glass wafer 141W, and heat affected zones (HAZs) which are impacted by stress are not generated.

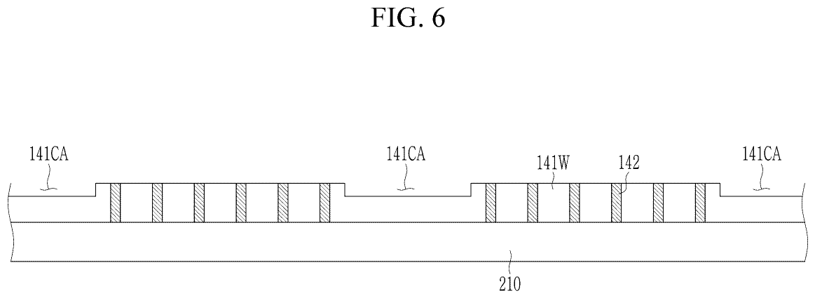

FIG. 6 is a cross-sectional view illustrating an operation of forming the through-glass vias (TGVs) 142 in the glass wafer 141W.

Referring to FIG. 6, the through-glass vias (TGVs) 142 may be formed by filling the insides of the through-holes 142H formed in the glass wafer 141W with a conductive material. In the embodiment, the through-glass vias (TGVs) 142 may be formed by forming seed metal layers and then performing electroplating, or by performing sputtering. In the embodiment, the through-glass vias (TGVs) 142 may be formed by completely filling the inside of the through-holes 142H with a conductive material. In the embodiment, the through-glass vias (TGVs) 142 may be formed by conformally forming a conductive material along the inner surface of the through-holes 142H and filling the remaining spaces of the through-holes 142H with a dielectric material. In the embodiment, the conductive material that fills the inside of the through-holes 142H may comprise at least one of copper, aluminum, tungsten, nickel, gold, tin, titanium, and alloys thereof. In the embodiment, the dielectric material that fills the inside of the through-holes 142H may comprise photoimageable dielectric (PID), glass fiber injected with a synthetic resin, such as a woven glass mat (glass-epoxy) impregnated with epoxy, polyimide, FR-4, resin cyanate ester, Teflon (PTFE), polyethylene ether, and a mixture thereof.

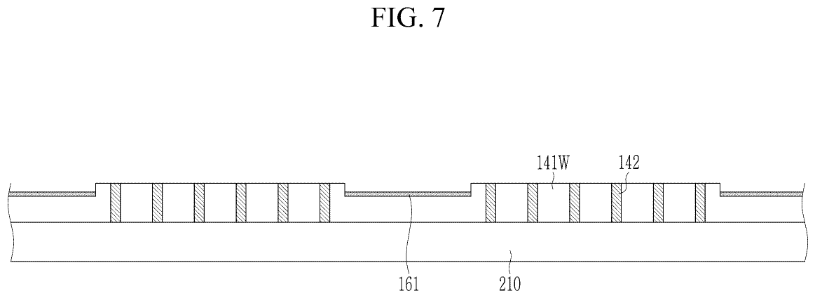

FIG. 7 is a cross-sectional view illustrating an operation of forming the lower electrode 161 inside the first cavities 141CA.

Referring to FIG. 7, the lower electrode 161 may be deposited inside the first cavities 141CA in order to form the first capacitor structure 160A embedded in the first cavity 141CA. The lower electrode 161 may be deposited through a photolithography process. In the embodiment, the process of depositing the lower electrodes 161 may be performed by sputtering. In the embodiment, the lower electrodes 161 may comprise at least one of aluminum, copper, chromium, nickel, tantalum, and alloys thereof.

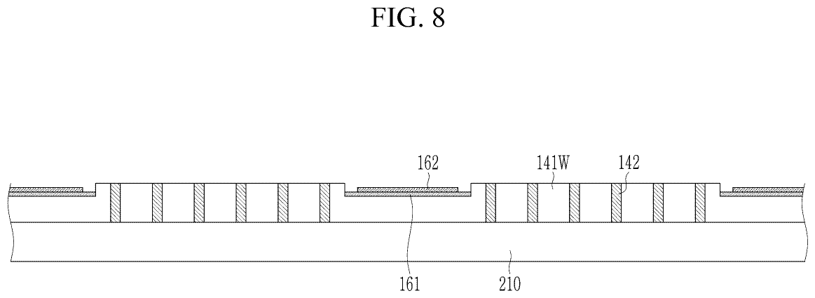

FIG. 8 is a cross-sectional view illustrating an operation of forming the dielectric layer 162 on the lower electrodes 161 inside the first cavities 141CA.

Referring to FIG. 8, the dielectric layer 162 may be deposited on the lower electrodes 161 inside the first cavities 141CA. In the embodiment, the dielectric layer 162 may be deposited through a photolithography process. In the embodiment, the process of depositing the dielectric layer 162 may be performed by atomic layer deposition (ALD), chemical vapor deposition (CVD), or sputtering. In the embodiment, the dielectric layer 162 may comprise AlO₂, Al₂O₃, ZrO₂, HfO₂, Nb₂O₅, CeO₂, TiO₂, Ta₂O₅, SiNx, or a combination thereof.

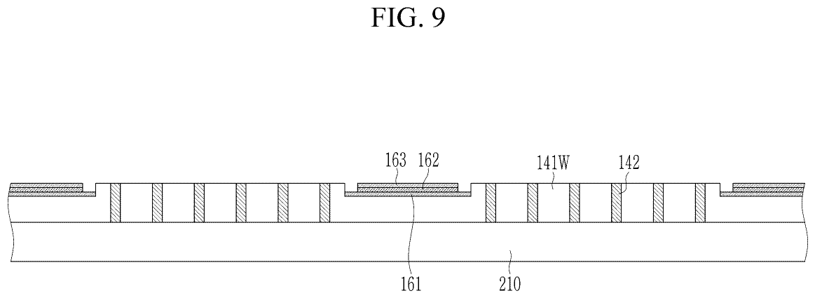

FIG. 9 is a cross-sectional view illustrating an operation of forming the upper electrode 163 on the dielectric layer 162 inside the first cavities 141CA.

Referring to FIG. 9, the upper electrode 163 may be formed on the dielectric layer 162 inside the first cavities 141CA. The upper electrode 163 may be deposited through a photolithography process. In the embodiment, the process of depositing the upper electrode 163 may be performed by sputtering. In the embodiment, the upper electrode 163 may comprise at least one of aluminum, copper, chromium, nickel, tantalum, and alloys thereof.

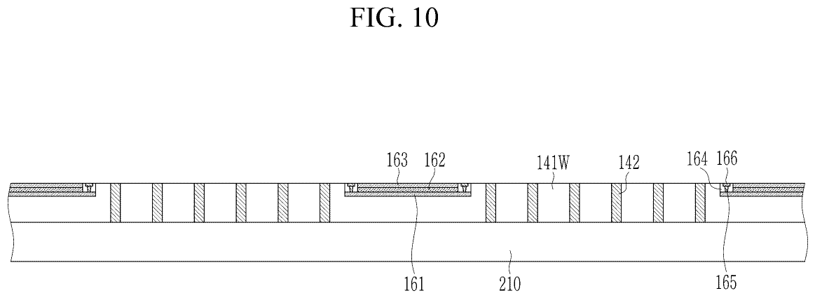

FIG. 10 is a cross-sectional view illustrating an operation of forming wiring lines that may be connected to the lower electrode 161.

Referring to FIG. 10, the via 165 on the lower electrode 161, the connection pad 166 on the via 165, and the dielectric 164 that surround the via 165 and the connection pad 166 may be formed. In the embodiment, the via 165 and the connection pad 166 may be formed by performing a photolithography process and sputtering. In the embodiment, the via 165 and the connection pad 166 may comprise at least one of copper, aluminum, tungsten, nickel, gold, tin, titanium, and alloys thereof. In the embodiment, the dielectric 164 may be formed by performing atomic layer deposition (ALD) or chemical vapor deposition (CVD). In the embodiment, the dielectric 164 may include a SiO₂, SiOC, SiOH, SiOCH, or low-k dielectric layer.

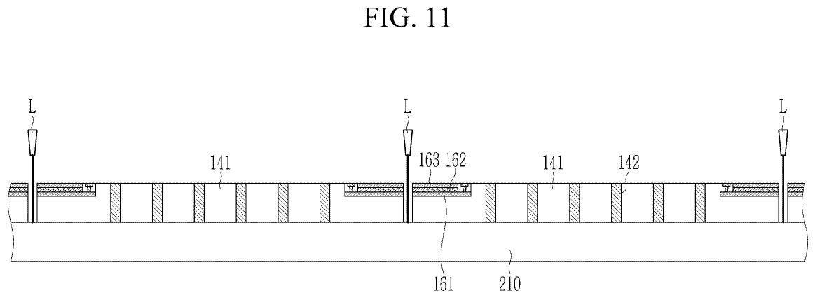

FIG. 11 is a cross-sectional view illustrating an operation of singulating the glass wafer 141W.

Referring to FIG. 11, the glass cores 141 may be singulated from the glass wafer 141W. In the embodiment, the operation of singulating may be performed by laser cutting. The first cavities 141CA may be divided into two half cavities 141HC by the laser cutting. The capacitor structure formed inside the first cavities 141CA may be divided into two first capacitor structures 160A by the laser cutting. The capacitor structure formed inside the first cavities 141CA includes a dummy region (or a scribe lane region) at a position where the laser cutting may be performed. Accordingly, even when the laser cutting is performed to divide the capacitor structure formed inside the first cavities 141CA into two first capacitor structures 160A, it does not affect the capacitance for decoupling of the two individual first capacitor structures 160A.

When cutting (drilling) is performed on the glass wafer 141W with the laser, around the laser cutting areas, microcracking may occur or heat affected zones (HAZs) which are impacted by stress may be generated. Since the operation of singulating on the glass wafer 141W may be a process of simply separating the glass wafer 141W into the glass cores 141 without affecting the elements, the operation of singulating on the glass wafer 141W may be performed by laser cutting. The surface shape of the glass cores 141 formed by performing the laser cutting has a shape different from the inner surface of the through-holes 142H and the first cavities 141CA formed through the composite process of modification by the laser beam and etching. In the embodiment, the surface roughness of the side surfaces of the glass cores 141 may be about 50 nm to about 5 μm.

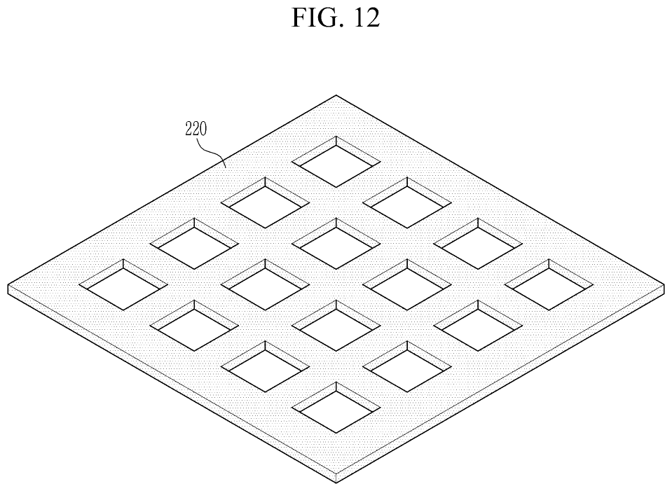

FIGS. 12 to 15 are drawings for explaining an operation of forming the core layer 140.

FIG. 12 is a drawing illustrating an operation of providing a frame 220.

Referring to FIG. 12, the frame 220 may be provided to perform a process of reinforcing the side surfaces of the first capacitor structures 160A exposed from the glass cores 141 and the side surfaces of the glass cores 141. The frame 220 include through-holes.

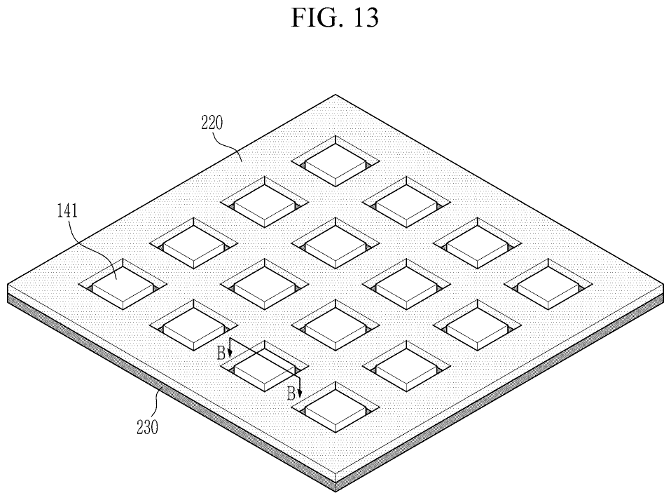

FIG. 13 is a drawing illustrating an operation of inserting the glass cores 141 into the frame 220.

Referring to FIG. 13, an adhesive member 230 may be attached to the lower surface of the frame 220. Thereafter, the glass cores 141 may be disposed inside the through-holes of the frame 220 on the adhesive member 230. In the embodiment, the adhesive member 230 may include polyimide tape.

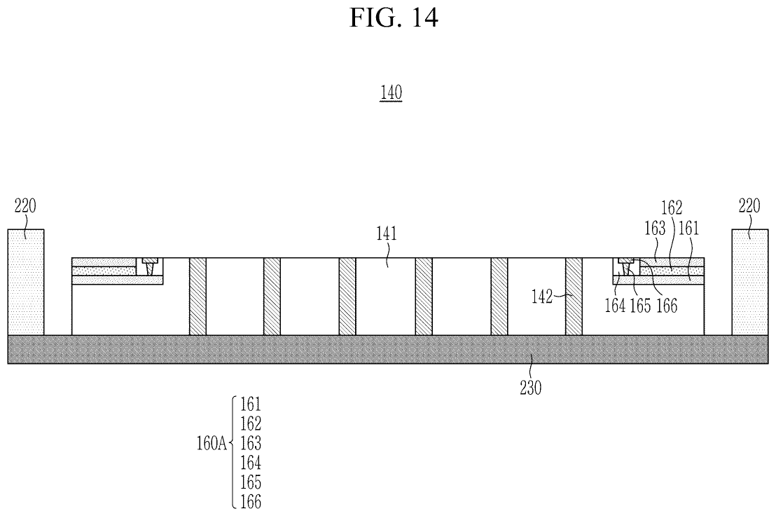

FIG. 14 is a cross-sectional view taken along line B-B′ of FIG. 13.

Referring to FIG. 14, the glass cores 141 may be disposed inside the through-holes of the frame 220 on the adhesive member 230.

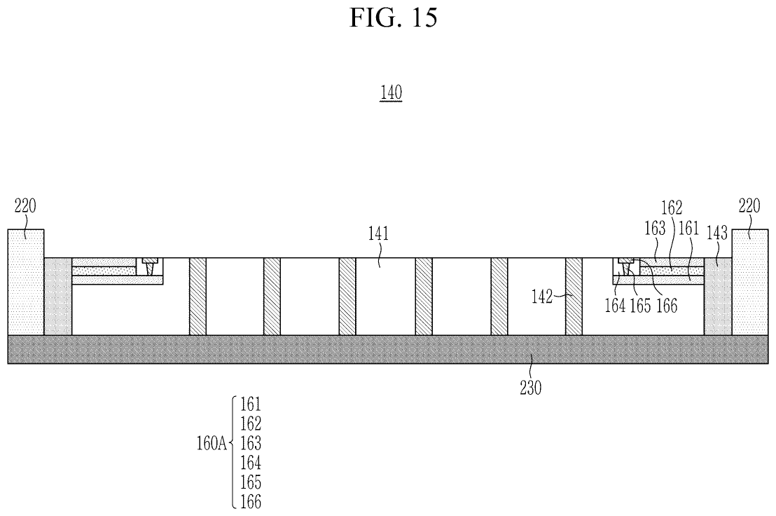

FIG. 15 is a cross-sectional view illustrating an operation of disposing the insulating member 143 on the side surfaces of the glass cores 141.

Referring to FIG. 15, the insulating member 143 may be inserted next to and around the side surfaces of the first capacitor structures 160A exposed from the glass cores 141 and the side surfaces of the glass cores 141, inside the through-holes of the frame 220. In the embodiment, the insulating member 143 may include Ajinomoto build-up film (ABF). In the embodiment, the insulating member 143 may be inserted into the through-holes of the frame 220 by lamination or dispensing.

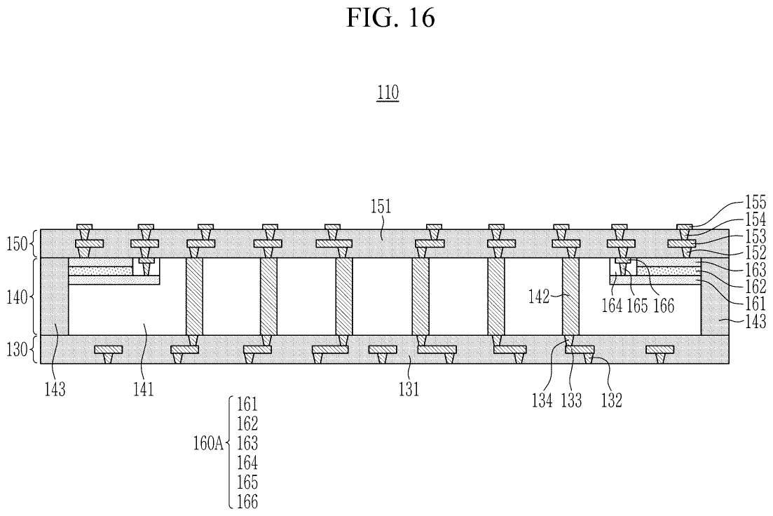

FIG. 16 is a cross-sectional view illustrating an operation of forming the glass substrate 110.

Referring to FIG. 16, the lower buildup structure 130 may be formed on a first surface (lower surface) of the core layer 140, and the upper buildup structure 150 may be formed on a second surface (upper surface) of the core layer 140. The second surface may be the opposite surface to the first surface. In the embodiment, the first dielectric 131 and the second dielectric 151 may be formed of an inorganic dielectric material or an organic dielectric material. In the embodiment, the first dielectric 131 and the second dielectric 151 may be formed by performing spin coating, chemical vapor deposition (CVD), atomic layer deposition (ALD), or a plasma-enhanced chemical vapor deposition (PECVD) process. In the embodiment, the first vias 132, the first conductive lines 133, the second vias 134, the third vias 152, the second conductive lines 153, the fourth vias 154, and the bonding pads 155 may comprise at least one of copper, aluminum, tungsten, nickel, gold, tin, titanium, and alloys thereof. In the embodiment, the first vias 132, the first conductive lines 133, the second vias 134, the third vias 152, the second conductive lines 153, the fourth vias 154, and the bonding pads 155 may be formed by performing a sputtering process. In other embodiments, the first vias 132, the first conductive lines 133, the second vias 134, the third vias 152, the second conductive lines 153, the fourth vias 154, and the bonding pads 155 may be formed by forming a seed metal layer and then performing electroplating.

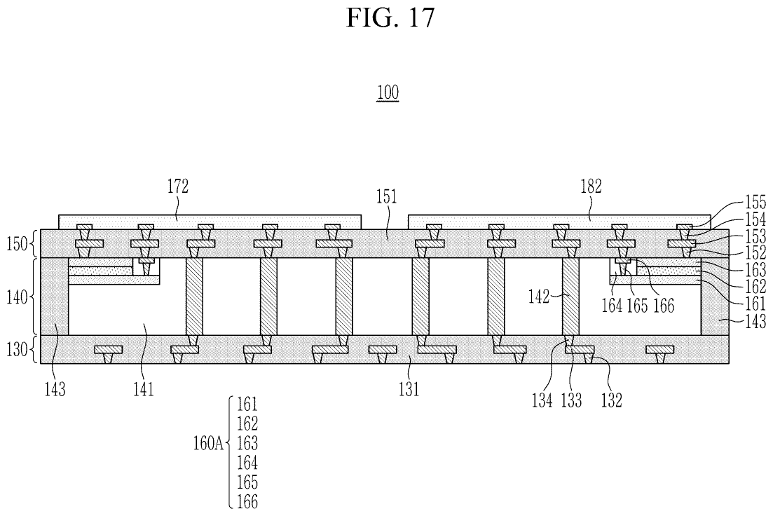

FIGS. 17 to 20 are cross-sectional views for explaining an operation of completing the semiconductor package 100 by mounting the first semiconductor die 170 and the second semiconductor die 180 on the glass substrate 110.

FIG. 17 is a cross-sectional view illustrating an operation of attaching the first insulating film 172 and the second insulating film 182 on the upper buildup structure 150.

Referring to FIG. 17, the first insulating film 172 and the second insulating film 182 may be attached around the bonding pads 155 on the upper buildup structure 150. In the embodiment, the first insulating film 172 and the second insulating film 182 may include non-conductive film (NCF). The non-conductive film (NCF) has adhesiveness and may be in an uncured state that can be deformed by an external force.

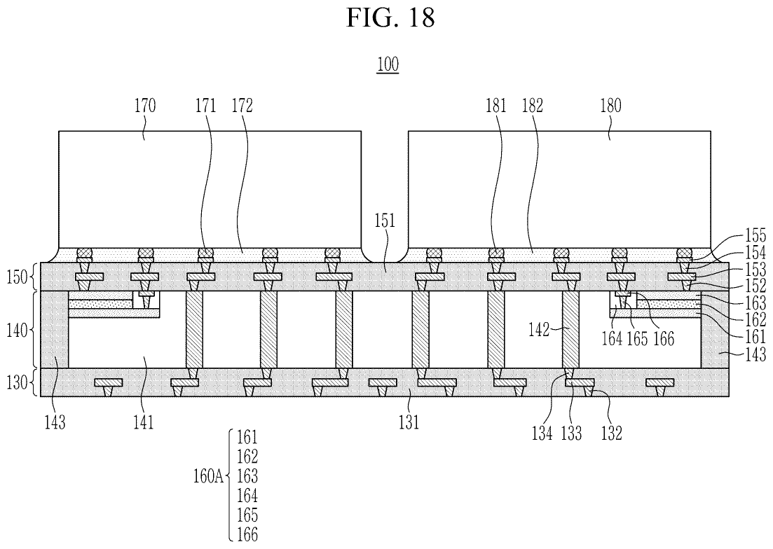

FIG. 18 is a cross-sectional view illustrating an operation of mounting the first semiconductor die 170 and the second semiconductor die 180 on the upper buildup structure 150.

Referring to FIG. 18, the first semiconductor die 170 may be bonded to the bonding pads 155, using the first connection members 171. The first connection members 171 provided on the first semiconductor die 170 passes through the first insulating film 172, and may be bonded to the bonding pads 155 inside the first insulating film 172. The second semiconductor die 180 may be bonded to the bonding pads 155, using the second connection members 181. The second connection members 181 provided on the second semiconductor die 180 passes through the second insulating film 182, and may be bonded to the bonding pads 155 inside the second insulating film 182, respectively.

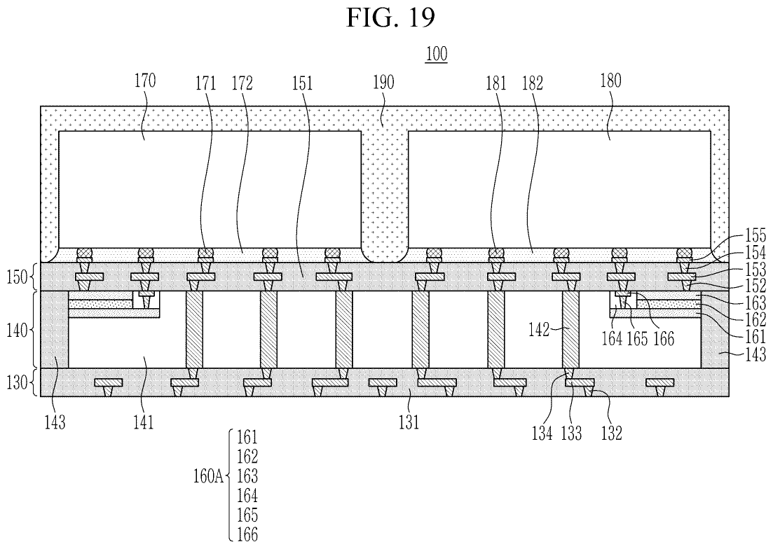

FIG. 19 is a cross-sectional view illustrating an operation of encapsulating the first semiconductor die 170, the first insulating film 172, the second semiconductor die 180, and the second insulating film 182 on the upper buildup structure 150 by the molding material 190.

Referring to FIG. 19, the first semiconductor die 170, the first insulating film 172, the second semiconductor die 180, and the second insulating film 182 may be covered on the upper buildup structure 150 by the molding material 190. In the embodiment, the process of encapsulating by the molding material 190 may include a compression molding or transfer molding process. In the embodiment, the molding material 190 may comprise an epoxy molding compound (EMC).

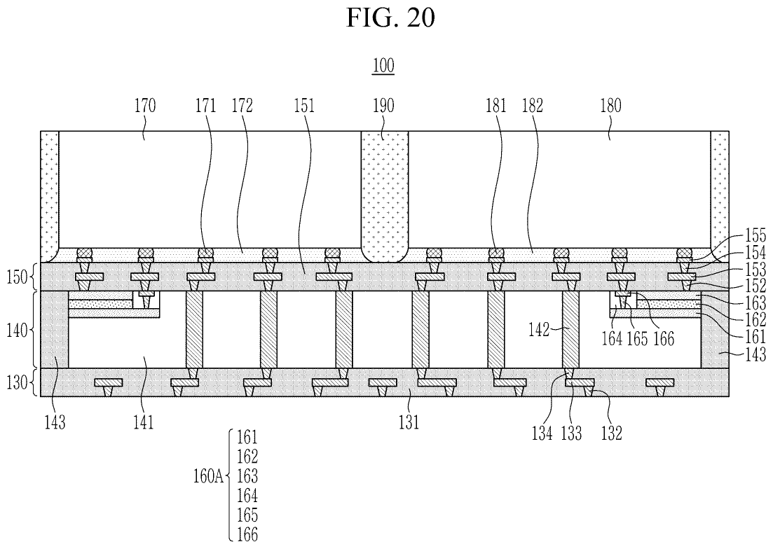

FIG. 20 is a cross-sectional view illustrating an operation of planarizing the molding material 190.

Referring to FIG. 20, in order to level the upper surface of the molding material 190, a planarizing process may be performed. In the embodiment, as the planarizing process, chemical mechanical polishing (CMP) may be performed. After the CMP process may be performed, the upper surface of the first semiconductor die 170 and the upper surface of the second semiconductor die 180 may be exposed.

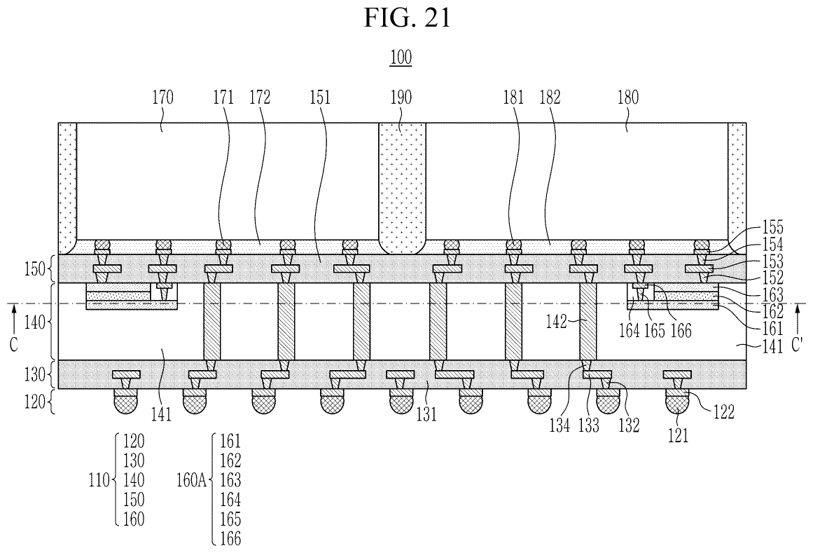

FIG. 21 is a cross-sectional view illustrating a semiconductor package 100 according to another embodiment.

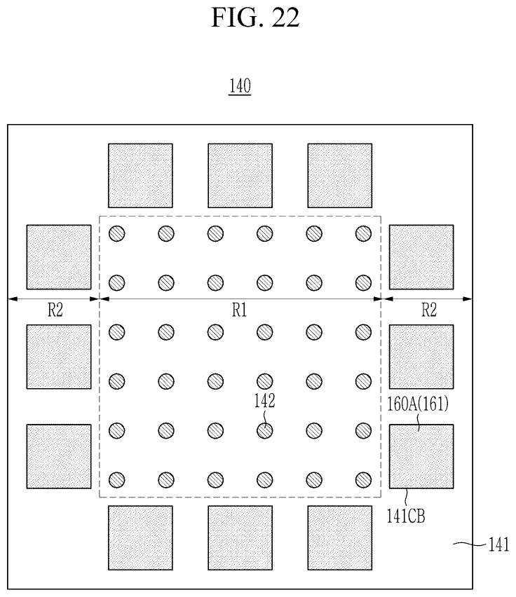

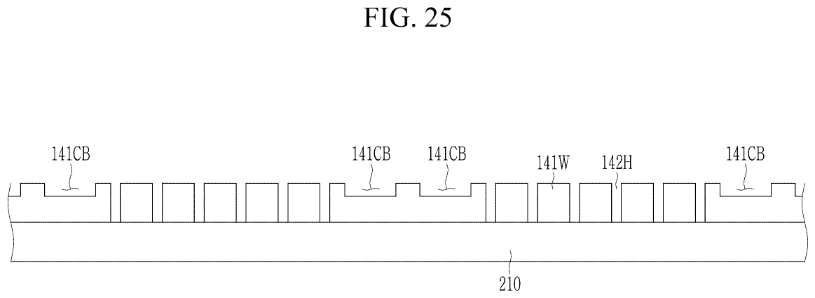

Referring to FIG. 21, a core layer 140 may include a glass core 141, through-glass vias (TGVs) 142, and second cavities 141CB (see FIG. 25). The first capacitor structure 160A may be disposed inside the second cavity 141CB (see FIG. 22) of the glass core 141. All of the side surfaces of the first capacitor structure 160A may be in contact with the glass core 141. In the embodiment, the first capacitor structure 160A may include thin film capacitors (TFCPs).

As for the content other than the content described with reference to FIG. 21, the content described with reference to FIG. 1 may be equally applied.

FIG. 22 is a plan view of the core layer 140 of the semiconductor package 100 of FIG. 21, taken along line C-C′.

Referring to FIG. 22, with respect to a dotted line, the glass core 141 of the core layer 140 includes the center region R1 inside the dotted line and the edge region R2 outside the dotted line. The center region R1 and the edge region R2 may be defined by dividing the plane of the glass core 141. In the center region R1, the through-glass vias (TGVs) 142 may be disposed. In the edge region R2, the second cavities 141CB may be positioned, and the first capacitor structures 160A may be disposed inside the second cavities 141CB. The side surfaces of the first capacitor structures 160A may be in contact with the glass core 141. In other embodiment, the core layer 140 may include fewer or more capacitor structures, which also is included in the scope of the present disclosure.

As for the content other than the content described with reference to FIG. 22, the content described with reference to FIG. 2 may be equally applied.

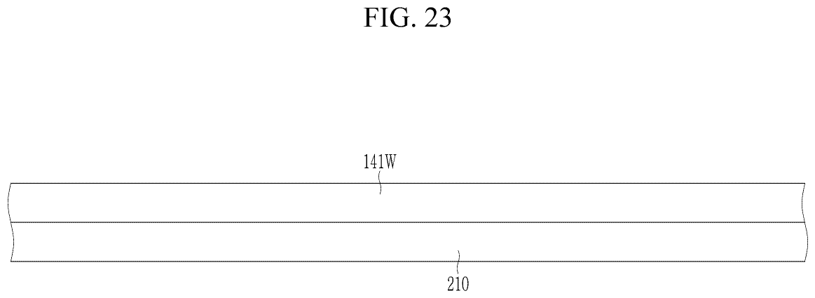

FIGS. 23 to 31 are cross-sectional views for explaining a method for manufacturing the core layer 140 of the semiconductor package 100 of FIG. 21.

FIG. 23 is a cross-sectional view illustrating an operation of providing the glass wafer 141W on a carrier 210.

Referring to FIG. 23, the glass wafer 141W on the carrier 210 may be provided. In the embodiment, the carrier 210 may comprise a silicon-based material such as glass or silicon oxide, an organic material, or other materials such as aluminum oxide, any combination of these materials, etc. In the embodiment, the glass wafer 141W may include borosilicate glass, quartz, or alkali-free glass.

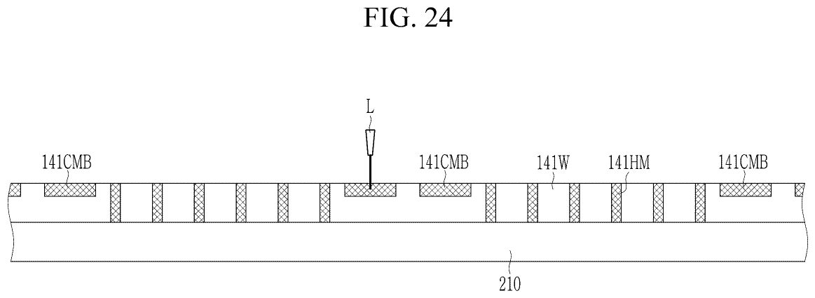

FIG. 24 is a cross-sectional view illustrating an operation of modifying the glass wafer 141W with a laser L.

Referring to FIG. 24, according to the patterns of through-holes 142H (see FIG. 23) to be formed in the center region R1 and according to the patterns of the second cavities 141CB to be formed in the edge region R2, the glass wafer 141W may be modified by a laser beam from the laser L. The laser beam from the laser L forms first modification patterns 141HM and third modification pattern 141CMB in the glass wafer 141W without destroying the glass wafer 141W. The first modification patterns 141HM may be patterns for forming the through-holes 142H. The third modification patterns 141CMB may be patterns for forming the second cavities 141CB. The laser beam modifies the mesh structure of the glass wafer 141W into a linear chain structure. The modification on the glass wafer 141W may be performed along the beam axis of the laser beam. The laser beam has the form of a pulse sequence and interacts with the glass wafer 141W. The pulse sequence may include single pulses. In an embodiment, the laser beam used for modification may have a pulse width shorter than about 100 ns. In an embodiment, the laser beam used for modification may have a pulse width shorter than about 1 fs.

FIG. 25 is a cross-sectional view illustrating an operation of etching the glass wafer 141W.

Referring to FIG. 25, by etching the glass wafer 141W, the through-holes 142H may be formed in the center region R1 and the second cavities 141CB may be formed in the edge region R2. In an embodiment, the operation of performing etching on the glass wafer 141W may be performed by isotropic wet etching. When the etching process may be performed, the portions of the glass wafer 141W that have not been modified into the linear chain structure may be rarely etched, and the first modification patterns 141HM and third modification patterns 141CMB of the glass wafer 141W that have been modified into the linear chain structure by the laser beam may be rapidly etched. Accordingly, etching may be performed along the outlines of the first modification patterns 141HM and the third modification patterns 141CMB by the laser.

The inner surface of the through-holes 142H and the second cavities 141CB formed through the process of the two operations of modification by the laser beam and etching has a shape different from the surface shape formed by performing laser cutting on the glass wafer 141W. In an embodiment, the inner surface of the through-holes 142H and the second cavities 141CB may have a porous shape or a wavy shape. In an embodiment, the inner surface of the through-holes 142H and the second cavities 141CB may have a shape in which contraction portions and extension portions may be regularly or irregularly formed. In an embodiment, the inner surface of the through-holes 142H and the second cavities 141CB may have a shape in which contraction portions and extension portions may be continuously or discontinuously extended. The shapes of the above-mentioned embodiments may be ultrafine shapes, and this ultrafine shape of the inner surface of the through-holes 142H and the second cavities 141CB ensures excellent adhesion strength to a conductive material or a dielectric material to be subsequently deposited on the inside of the through-holes 142H and the second cavities 141CB.

The surface roughness of the inner surface of the through-holes 142H and the second cavities 141CB formed through the process of the two operations of modification by the laser beam and etching has a value smaller than that of the surface roughness of the surface that is formed by performing laser cutting on the glass wafer 141W. In an embodiment, the surface roughness of the inner surface of the through-holes 142H and the second cavities 141CB may be about 2 nm to about 40 nm. This low surface roughness of the inner surface of the through-holes 142H and the second cavities 141CB improves the reliability of the through-glass vias (TGVs) 142 that may be formed by filling the through-holes 142H with a conductive material and the reliability of the first capacitor structures 160A that may be formed inside the second cavities 141CB.

When cutting (drilling) is performed on the glass wafer 141W with the laser in order to form the through-holes 142H or the second cavities 141CB, around the laser cutting areas, microcracking may occur or heat affected zones (HAZs) which are impacted by stress may be generated, resulting in deterioration of the mechanical characteristics of the glass wafer 141W. According to the present disclosure, since the composite process of modification by the laser beam and etching may be performed to form the through-holes 142H and the second cavities 141CB in the glass wafer 141W, microcracking does not occur in the glass wafer 141W, and heat affected zones (HAZs) which are impacted by stress are not generated.

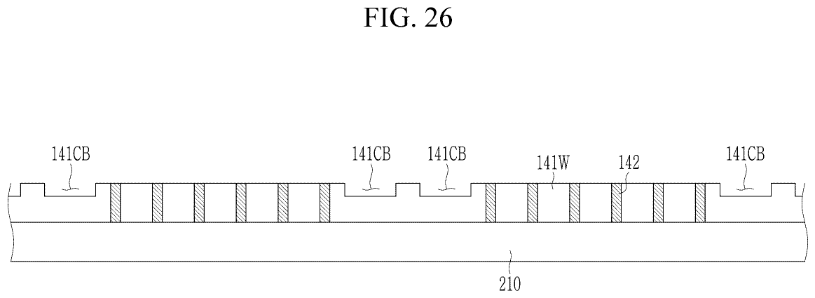

FIG. 26 is a cross-sectional view illustrating an operation of forming the through-glass vias (TGVs) 142 in the glass wafer 141W.

Referring to FIG. 26, the through-glass vias (TGVs) 142 may be formed by filling the insides of the through-holes 142H formed in the glass wafer 141W with a conductive material. In the embodiment, the through-glass vias (TGVs) 142 may be formed by completely filling the inside of the through-holes 142H with a conductive material. In the embodiment, the through-glass vias (TGVs) 142 may be formed by conformally forming a conductive material along the inner surface of the through-holes 142H and filling the remaining spaces of the through-holes 142H with a dielectric material. In the embodiment, the conductive material that fills the inside of the through-holes 142H may comprise at least one of copper, aluminum, tungsten, nickel, gold, tin, titanium, and alloys thereof. In the embodiment, the dielectric material that fills the inside of the through-holes 142H may comprise photoimageable dielectric (PID), glass fiber injected with a synthetic resin, such as a woven glass mat (glass-epoxy) impregnated with epoxy, polyimide, FR-4, resin cyanate ester, Teflon (PTFE), polyethylene ether, and a mixture thereof.

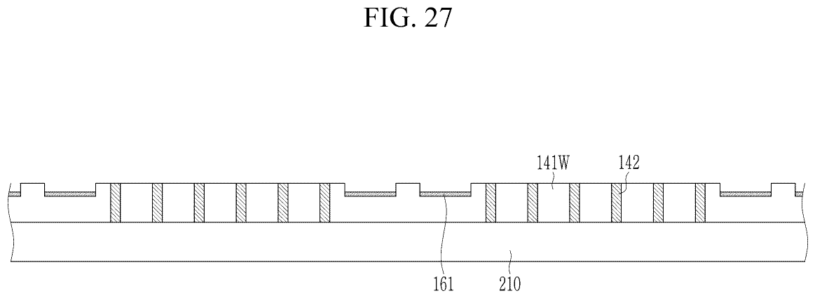

FIG. 27 is a cross-sectional view illustrating an operation of forming the lower electrodes 161 inside the second cavities 141CB.

Referring to FIG. 27, the lower electrodes 161 may be deposited inside the second cavities 141CB in order to form the first capacitor structure 160A embedded in the second cavity 141CB. The lower electrodes 161 may be deposited through a photolithography process. In the embodiment, the process of depositing the lower electrodes 161 may be performed by sputtering. In the embodiment, the lower electrodes 161 may comprise at least one of aluminum, copper, chromium, nickel, tantalum, and alloys thereof.

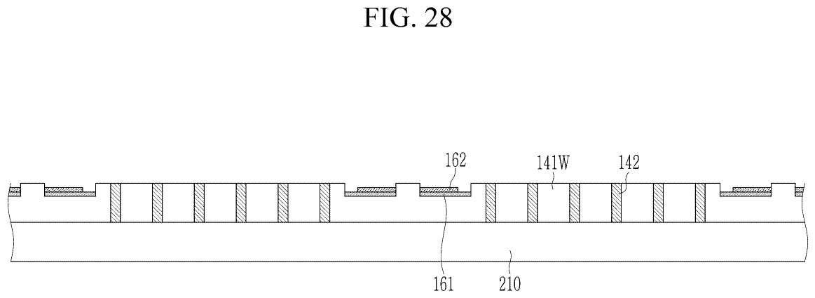

FIG. 28 is a cross-sectional view illustrating an operation of forming the dielectric layers 162 on the lower electrodes 161 inside the second cavities 141CB.

Referring to FIG. 28, the dielectric layer 162 may be deposited on the lower electrodes 161 inside the second cavities 141CB. In the embodiment, the dielectric layers 162 may be deposited through a photolithography process. In the embodiment, the process of depositing the dielectric layer 162 may be performed by atomic layer deposition (ALD), chemical vapor deposition (CVD), or sputtering. In the embodiment, the dielectric layer 162 may comprise AlO₂, Al₂O₃, ZrO₂, HfO₂, Nb₂O₅, CeO₂, TiO₂, Ta₂O₅, SiNx, or a combination thereof.

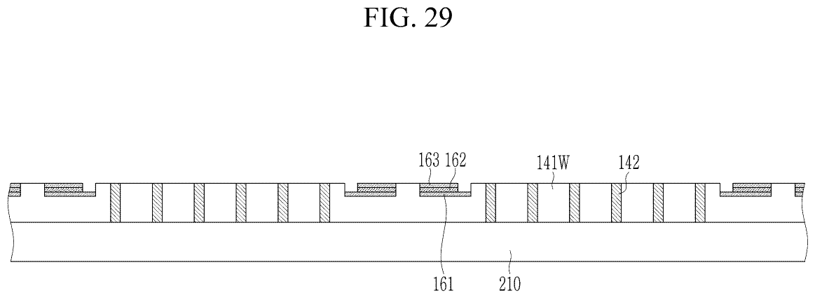

FIG. 29 is a cross-sectional view illustrating an operation of forming the upper electrodes 163 on the dielectric layers 162 inside the second cavities 141CB.

Referring to FIG. 29, the upper electrodes 163 may be deposited on the dielectric layers 162 inside the second cavities 141CB. The upper electrodes 163 may be deposited through a photolithography process. In the embodiment, the process of depositing the upper electrodes 163 may be performed by sputtering. In the embodiment, the upper electrodes 163 may comprise at least one of aluminum, copper, chromium, nickel, tantalum, and alloys thereof.

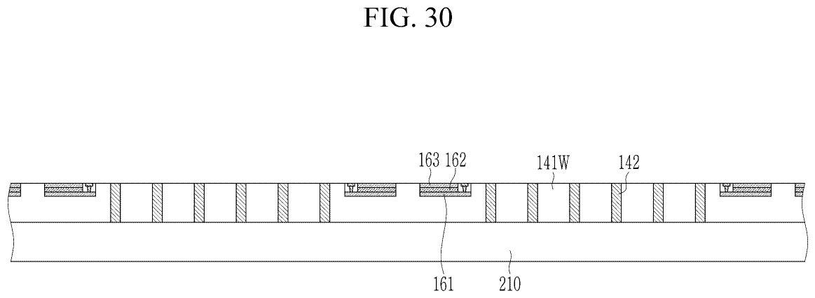

FIG. 30 is a cross-sectional view illustrating an operation of forming wiring lines that may be connected to the lower electrodes 161.

Referring to FIG. 30, the vias 165 on the lower electrodes 161, the connection pads 166 on the vias 165, and the dielectrics 164 that surround the vias 165 and the connection pads 166 may be formed. In the embodiment, the vias 165 and the connection pads 166 may be formed through a photolithography process and sputtering. In the embodiment, the vias 165 and the connection pads 166 may comprise at least one of copper, aluminum, tungsten, nickel, gold, tin, titanium, and alloys thereof. In the embodiment, the dielectrics 164 may be formed by performing atomic layer deposition (ALD) or chemical vapor deposition (CVD). In the embodiment, the dielectrics 164 may include a SiO₂, SiOC, SiOH, SiOCH, or low-k dielectric layer.

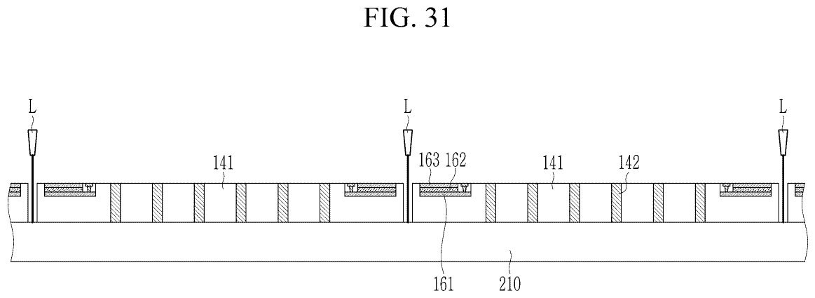

FIG. 31 is a cross-sectional view illustrating an operation of singulating on the glass wafer 141W.

Referring to FIG. 31, the glass cores 141 may be singulated from the glass wafer 141W. In the embodiment, the operation of singulating may be performed by laser cutting. When cutting (drilling) may be performed on the glass wafer 141W with the laser, around the laser cutting areas, microcracking may occur or heat affected zones (HAZs) which are impacted by stress may be generated. Since the operation of singulating the glass wafer 141W may be a process of simply separating the glass wafer 141W into the glass cores 141 without affecting the elements, the operation of singulating on the glass wafer 141W may be performed by laser cutting. The surface shape of the glass cores 141 formed by performing the laser cutting has a shape different from the inner surface of the through-holes 142H and the second cavities 141CB formed through the composite process of modification by the laser beam and etching. In the embodiment, the surface roughness of the side surfaces of the glass cores 141 may be about 50 nm to about 5 μm.

Subsequently, as for a manufacturing method of completing the semiconductor package 100 of FIG. 21, the content described with reference to FIGS. 16 to 20 may be equally applied.

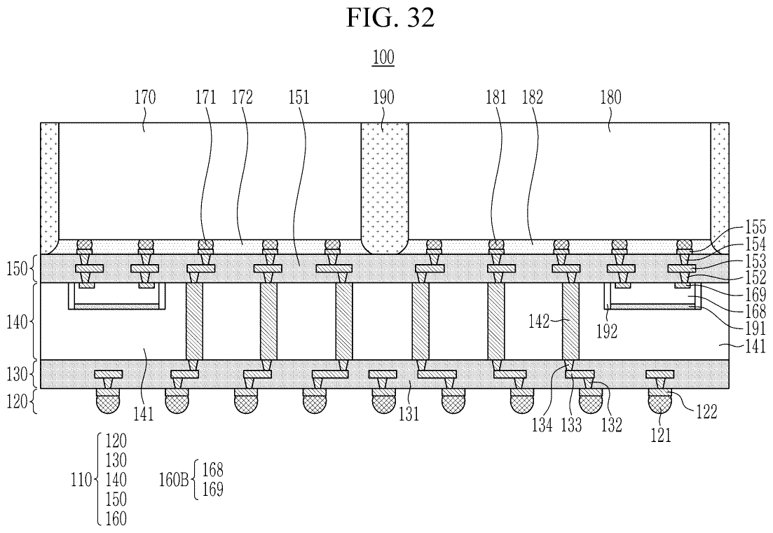

FIG. 32 is a cross-sectional view illustrating a semiconductor package 100 of a further embodiment.

Referring to FIG. 32, a core layer 140 may include a glass core 141, through-glass vias (TGVs) 142, and second cavities 141CB (see FIG. 25). Each of second capacitor structures 160B may be disposed inside the second cavities 141CB of the glass core 141. All of the side surfaces of the second capacitor structure 160B may be in contact with the glass core 141. The second capacitor structures 160B may be attached inside the second cavities 141CB of the glass core 141 by each of adhesive members 191. The second capacitor structure 160B may include chip base 168, and connection pads 169 inside the chip base 168. The second capacitor structure 160B may be a premanufactured capacitor chip. The connection pads 169 may be electrically connected to the third vias 152 of the upper buildup structure 150. In the embodiment, the second capacitor structures 160B may include multilayer ceramic capacitors (MLCCs), or integrated stack capacitors (ISCs).

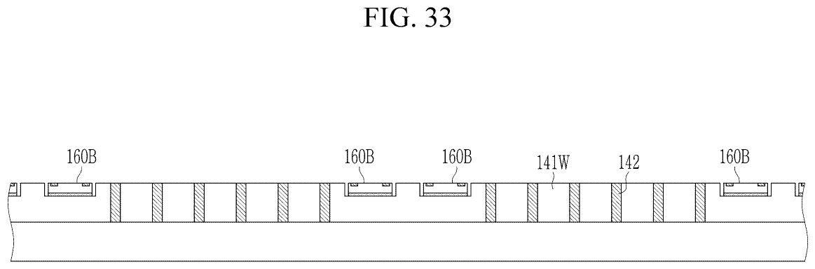

FIGS. 33 to 36 are cross-sectional views for explaining a method for manufacturing the core layer 140 of the semiconductor package 100 of FIG. 32. As for an operation of providing a glass wafer 141W to an operation of forming through-glass vias (TGVs) 142 inside the glass wafer 141W, the content described with reference to FIGS. 23 to 26 may be equally applied.

FIG. 33 is a cross-sectional view illustrating an operation of mounting the second capacitor structures 160B inside the second cavities 141CB.

Referring to FIG. 33, the second capacitor structures 160B may be mounted inside the second cavities 141CB. The second capacitor structures 160B may be attached inside the second cavities 141CB by the adhesive members 191. In the embodiment, the adhesive members 191 may include die attach film (DAF). In the embodiment, the adhesive members 191 may include adhesive tape, Ag paste, an epoxy resin, or polyimide. In the embodiment, the adhesive members 191 may comprise a thermal interface material (TIM). In an embodiment, the thermal interface material (TIM) may include thermal paste, thermal pads, a phase change material (PCM), or a metallic material. In an embodiment, the thermal interface material (TIM) may include grease.

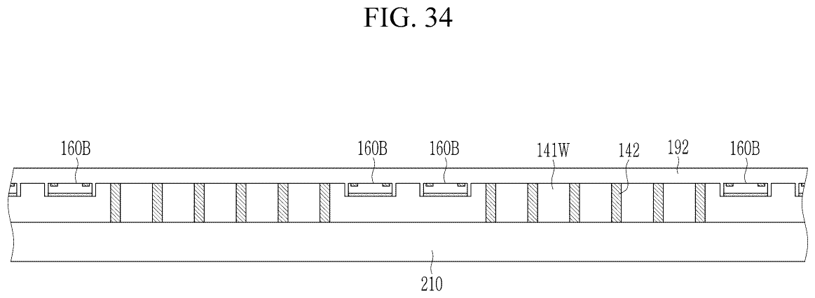

FIG. 34 is a cross-sectional view illustrating an operation of encapsulating the second capacitor structures 160B and the adhesive members 191 on the second cavities 141CB by a molding material 192.

Referring to FIG. 34, the second capacitor structures 160B and the adhesive members 191 may be covered on the second cavities 141CB by the molding material 192. In the embodiment, the process of encapsulating by the molding material 192 may include a compression molding or transfer molding process. In the embodiment, the molding material 192 may comprise an epoxy molding compound (EMC).

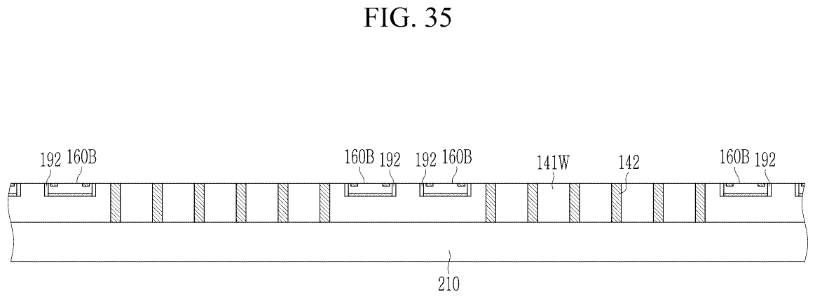

FIG. 35 is a cross-sectional view illustrating an operation of planarizing the molding material 192.

Referring to FIG. 35, in order to level the upper surface of the molding material 192, a planarizing process may be performed. In the embodiment, as the planarizing process, chemical mechanical polishing (CMP) may be performed. After the CMP process may be performed, the upper surfaces of the second capacitor structures 160B may be exposed.

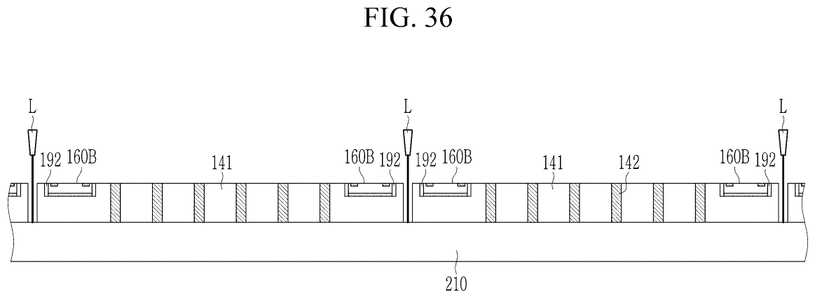

FIG. 36 is a cross-sectional view illustrating an operation of singulating on the glass wafer 141W.

Referring to FIG. 36, the glass cores 141 may be singulated from the glass wafer 141W. In the embodiment, the operation of singulating may be performed by laser cutting.

Subsequently, as for a manufacturing method of completing the semiconductor package 100 of FIG. 32, the content described with reference to FIGS. 16 to 20 may be equally applied.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. A glass substrate comprising:
a core layer including
a glass core including a center region and an edge region around the center region, which are defined by dividing a plane of the glass core,
a plurality of through-glass vias inside the glass core in the center region, and
a plurality of cavities in the edge region; and
a plurality of capacitor structures in the plurality of cavities.

2. The glass substrate of claim 1, wherein
each of the plurality of cavities includes a half cavity.

3. The glass substrate of claim 2, wherein
the core layer further includes an insulating member next to the glass core, and
the insulating member is around the glass core.

4. The glass substrate of claim 3, wherein
a side surface of each of the plurality of capacitor structures is exposed from the glass core due to the half cavity, and
the insulating member surrounds the side surface of each of the plurality of capacitor structures.

5. The glass substrate of claim 3, wherein
the insulating member includes an Ajinomoto build-up film (ABF).

6. The glass substrate of claim 1, wherein
each of the plurality of capacitor structures includes a multilayer ceramic capacitor (MLCC), a thin film capacitor (TFCP), or an integrated stack capacitor (ISC).

7. The glass substrate of claim 1, wherein
a surface roughness of an inner surface of each of the plurality of cavities is smaller than a surface roughness of side surfaces of the glass core.

8. The glass substrate of claim 1, wherein
the surface roughness of an inner surface of each of the plurality of cavities is 2 nm to 40 nm.

9. The glass substrate of claim 1, wherein
the surface roughness of side surfaces of the glass core is 50 nm to 5 μm.

10. The glass substrate of claim 1, wherein
each of the plurality of cavities includes an inner surface having a surface shape resulting from laser modification and etching, and
the glass core includes side surfaces having a surface shape resulting from laser cutting.

11. A semiconductor package comprising:
a glass substrate including
a core layer,
a first buildup structure on a first surface of the core layer,
a second buildup structure on a second surface of the core layer, the second surface of the core layer being opposite the first surface of the core layer, and
a plurality of capacitor structures inside the core layer; and
a semiconductor die on the glass substrate, wherein
the core layer includes
a glass core including a center region and an edge region around the center region, which are defined by dividing a plane of the glass core,
a plurality of through-glass vias inside the glass core in the center region, and
a plurality of cavities in the edge region, and
a plurality of capacitor structures in the plurality of cavities.

12. A method for manufacturing a glass substrate, the method comprising:
providing a glass wafer including a plurality of glass cores, wherein each of the plurality of glass cores includes a center region and an edge region around the center region;
modifying the glass wafer with a laser, the modifying the glass wafer including forming first modification patterns in in the center region and second modification patterns in the edge region;
performing etching on the glass wafer, the performing etching forming a plurality of through-holes in the center region by removing the first modification patterns and forming a plurality of cavities in the edge region by removing the second modification patterns;
forming a plurality of through-glass vias by filling the plurality of through-holes with a conductive material;
forming capacitor structures in the plurality of cavities; and
singulating a plurality of glass cores from the glass wafer.

13. The method according to claim 12, wherein
the singulating is performed by laser cutting.

14. The method according to claim 13, wherein
the singulating includes separating the plurality of cavities into half cavities by the laser cutting.

15. The method according to claim 13, wherein
the singulating includes separating each of the capacitor structures into two capacitor structures by the laser cutting, and
the laser cutting is performed on the glass wafer.

16. The method according to claim 15, further comprising:
after the singulating, surrounding side surfaces of the capacitor structures, exposed by the laser cutting, with an insulating member.

17. The method according to claim 12, wherein
a surface roughness of inner surfaces of the plurality of through-holes is smaller than a surface roughness of side surfaces of the plurality of glass cores obtained by the singulating.

18. The method according to claim 12, wherein
the forming the capacitor structures includes:
depositing lower electrodes;
depositing a dielectric layer on the lower electrodes; and
depositing an upper electrode on the dielectric layer.

19. The method according to claim 12, wherein
the capacitor structures include a capacitor chip, and
the forming the capacitor structures includes mounting the capacitor chip inside the plurality of cavities, respectively.

20. The method according to claim 12, wherein
the performing etching on the glass wafer is performed by isotropic wet etching.
